(19) United States
(12) Patent Application Publication
(10) Pub. No.: US 2024/0154389 A1
(43) Pub. Date: May 9, 2024

(54) Multi-Electrode Device Using Vertical Cavity Surface Emitting Laser Array with Improved Electro-to-Optical Frequency Response

(71) Applicant: National Central University, Taoyuan City (TW)

(72) Inventor: Jin-Wei Shi, Taoyuan City (TW)

(21) Appl. No.: 18/103,546

(22) Filed: Jan. 31, 2023

(30) Foreign Application Priority Data
Nov. 8, 2022 (TW) 111142594

(51) Int. Cl. H01S 5/183; H01S 5/062; H01S 5/343; H01S 5/42

(52) U.S. Cl. CPC H01S 5/18394; H01S 5/0624; H01S 5/34313; H01S 5/423

(57) ABSTRACT

A multi-electrode device is provided. The device improves electrical-to-optical (E-O) frequency response in vertical cavity surface emitting laser (VCSEL) array. An electrode is used in a near quasi-single-mode (QSM) VCSEL array having zinc diffusion apertures for enhancing high-speed data transmission. By forming a distance less than 20 microns between the centers of every two neighboring apertures in the VCSEL array being compact 2×2-coupled, high-speed data transmission is significantly enhanced. The present invention exhibits good electro-optical frequency response suppression and good 3-decibel E-O bandwidth. Concerning the maximum QSM optical output power and the Gaussian-like optical far-field with a narrow diverging angle, significant improvement in dynamic performance do not sacrifice static performance. Thus, the present invention obtains a better eye pattern for 32 gigabits per second (Gbit/s); and, under a moderate total bias current of 20 milli-amperes, 32 Gbit/s error-free transmission can be realized on a 500-meter multimode optical fiber.

### TECHNICAL FIELD OF THE INVENTION

The present invention relates to a vertical-cavity surface-emitting laser (VCSEL) array with electrical-to-optical (E-O) frequency response; more particularly, to digging a light-emission aperture in each of dumbbell-shaped VCSEL units of the VCSEL array with a distance between every neighboring two of the light-emission apertures less than 20 microns (μm) along with electrodes whose number are not smaller than two, where each of the electrodes is injected with a different current to make the VCSEL array synthesized for controlling the shape of electrical-to-optical (E-O) frequency response.

### DESCRIPTION OF THE RELATED ARTS

The development of high-brightness, high-speed single-mode (SM) VCSEL arrays is critical to many applications, such as optical wireless communication (OWC) channel, laser ranging and sensing, multi-core fiber optical communication channel, etc. For a VCSEL array, it is very important to have a high-brightness, high-speed SM output, so that the diffraction loss in the wireless communication channel is reduced, the ranging distance of the sensing system is increased, and good coupling efficiency between the VCSEL array and the fiber is formed. There are many methods for achieving high SM power, which are done by reducing oxide aperture (<3 μm), zinc (Zn) diffusion, photonic crystal, and anti-guiding (leakage) cavity structure. However, the high-power SM VCSELs usually cause low-frequency rolloff and relative intensity noise (RIN) peaks in E-O frequency response owing to insufficient spatial hole burning (SHB), which leads to large signal transmission degradation.

In a conventional VCSEL array, each VCSEL cell is usually a spacer pillar etched into a substrate and the cells are connected in parallel by a common electrode on top of a wafer. Nevertheless, this layout makes optical phase coupling between neighboring VCSELs difficult, since the refractive index contrast between the active platform and the air is strong as forming a strong evanescent wave loss. Hence, the prior art does not fulfill all users' requests on actual use.

### SUMMARY OF THE INVENTION

The main purpose of the present invention is to provide a multi-electrode device using a VCSEL Array with a novel near quasi-single-mode (QSM) electrode having zinc diffusion apertures inside for effectively improving high-speed data transmission, where a distance less than 20 μm between every neighboring two light-emission apertures in a compact 2×2 coupled VCSEL array is formed; with the excitation of multi-electrode (e. g. at least two electrodes as an example with one for direct current (DC) injection and the other is for DC+radio frequency (RF) signal injection), significant enhancement of high-speed data transmission is obtained; the multi-electrode device exhibits the VCSEL array in greater E-O frequency response suppression and greater 3-decibel E-O bandwidth; in terms of maximum QSM optical output power and Gaussian-like optical far-field diagram with a narrow diverging angle, dramatic improvement in dynamic performance do not come at the expense of any degradation in static performance; the split multi-electrode leads to good quality of eye pattern at 32 gigabits per second (Gbit/s); and, under a moderate total bias current of 20 milli-amperes, 32 Gbit/s error-free transmission is realized on a 500-meter multimode optical fiber.

To achieve the above purpose, the present invention is a multi-electrode device using a VCSEL array with improved E-O frequency response, comprising a VCSEL array of a plurality of arranged VCSEL units, where a light-emission aperture is set on each of the VCSEL units in the VCSEL array; between every neighboring two of the light-emission apertures, a distance from a center of one of the light-emission apertures to a center of the other one of the light-emission apertures is less than 20 μm; electrodes whose number are not smaller than two are assembled; and each of the electrodes is injected with a different current to control the shape of E-O frequency response. Accordingly, a novel multi-electrode device using a VCSEL array with improved E-O frequency response is obtained.

### BRIEF DESCRIPTION OF THE DRAWINGS

The present invention will be better understood from the following detailed description of the preferred embodiment according to the present invention, taken in conjunction with the accompanying drawings, in which

FIG. 1A˜FIG. 1C are the structural views showing the 2×2 vertical cavity surface emitting laser (VCSEL) arrays of the present invention and the prior art;

FIG. 2A˜FIG. 2C are the views showing the L-I and I-V curves of the present invention and the prior art;

FIG. 3A˜FIG. 3C are the views showing the output spectrums of the present invention and the prior art under different bias currents;

FIG. 4A˜FIG. 4C are the views showing the one-dimensional (1D) and two-dimensional (2D) far-fields of the present invention and the prior art under different bias currents;

FIG. 5A˜FIG. 5C are the views showing the electrical-to-optical (E-O) frequency responses of the present invention and the prior art under different bias currents;

FIG. 6A and FIG. 6B are the views showing the eye patterns of back-to-back (BTB) 32 gigabits per second (Gbit/s) transmission of the present invention and the prior art;

FIG. 7A and FIG. 7B are the views showing the eye patterns of BTB 32 Gbit/s transmission of the present invention with the different currents injected into the electrodes at two sides;

FIG. 8A˜FIG. 8C are the views showing the 2D near-fields of the present invention and the prior art under different bias currents;

FIG. 9A˜FIG. 9D are the views showing the structures and L-I curves of the 7×7 VCSEL arrays of the present invention and the prior art under different bias currents; and

FIG. 10 is the view showing the 2D near fields, the 1 D and 2D far fields, and the E-O frequency responses of the present invention and the prior art, both using the 7×7-coupled VCSEL array under different bias currents.

### DESCRIPTION OF THE PREFERRED EMBODIMENT

The following description of the preferred embodiment is provided to understand the features and the structures of the present invention.

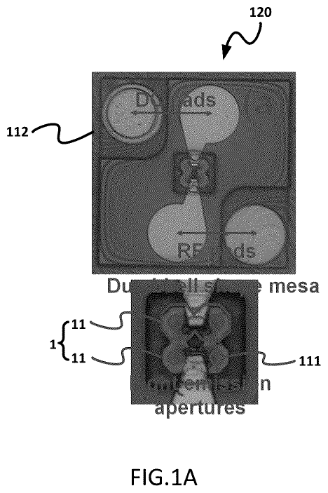

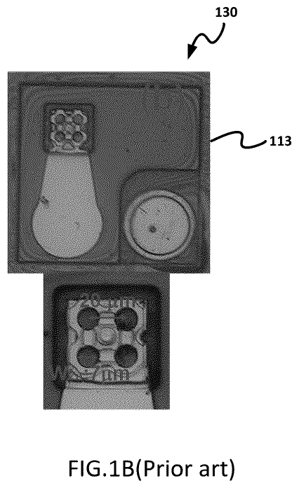

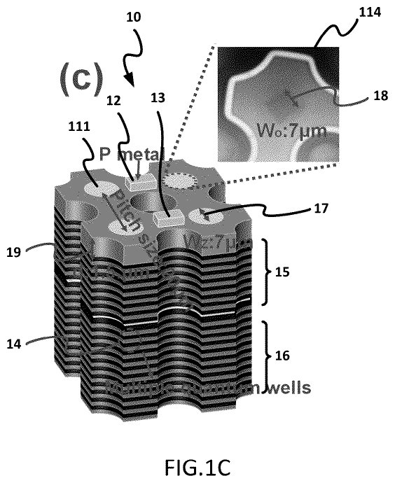

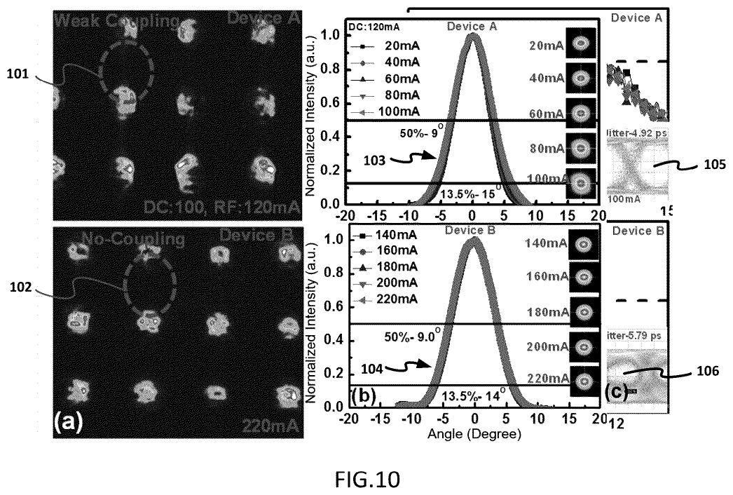

Please refer to FIG. 1A˜FIG. 10, which are structural views showing 2×2 VCSEL arrays of the present invention and a prior art; views showing L-I and I-V curves of the present invention and the prior art; views showing output spectrums of the present invention and the prior art under different bias currents; views showing 1 D and 2D far-fields of the present invention and the prior art under different bias currents; views showing E-O frequency responses of the present invention and the prior art under different bias currents; views showing eye patterns of BTB 32 gigabits per second (Gbit/s) transmission of the present invention and the prior art; views showing eye patterns of BTB 32 Gbit/s transmission of the present invention with different currents injected into the electrodes at two sides; views showing 2D near-fields of the present invention and the prior art under different bias currents; views showing structures and L-I curves of 7×7 VCSEL arrays of the present invention and the prior art under different bias currents; and a view showing 2D near fields, 1 D and 2D far fields, and E-O frequency responses of the present invention and the prior art, both using a 7×7-coupled VCSEL array under different bias currents. As shown in the figures, the present invention is a multi-electrode device using a VCSEL Array with improved E-O frequency response, where multiple electrodes are used to synthesize E-O frequency response of a VCSEL array and not limited to two electrodes in a following preferred embodiment. Therewith, a light-emission aperture is dug in each of dumbbell-shaped VCSEL units of the VCSEL array; between every neighboring two of the light-emission apertures, a distance from a center of one of the light-emission apertures to a center of the other one of the light-emission apertures is less than 20 microns (μm); and electrodes whose number are not smaller than two are used with each of the electrodes injected with a different current for thus making the VCSEL array synthesized.

The preferred embodiment is a multi-electrode device using a VCSEL array, whose structure is shown in FIG. 1A˜FIG. 1C. Diagram (a) and Diagram (b) are top-down diagrams of 2×2 VCSEL arrays; Diagram (a) shows the VCSEL array 1 of the present invention 120 and Diagram (b) shows that of a prior art 130 as a reference, where enlarged illustrations 112,113 show the active light-emission apertures 111 of the present invention 120 and that of the prior art 130; and Diagram (c) is a three-dimensional conceptual diagram of the active light-emission aperture 111 of the present invention 120, where an illustration 114 shows the infrared photography of the light-emission aperture 111 during wet oxidation. With the VCSEL array 1 shown in FIG. 1A, the present invention 120 comprises a plurality of arranged dumbbell-shaped VCSEL units 11. The VCSEL array 1 uses zinc (Zn) diffusion apertures and oxide-relief apertures to control the number of optical modes in output spectrums and to relax resistor-capacitor (RC)-limited bandwidth, respectively. A light-emission aperture 111 is set in each of the VCSEL units 11; and, between every neighboring two of the light-emission apertures 111, a distance from a center of one of the light-emission apertures 111 to a center of the other one of the light-emission apertures 111 is less than 20 μm. Electrodes whose number are not smaller than two are assembled. Two electrodes 12,13 are used in the preferred embodiment as an example, where each of the electrodes 12,13 is injected with a different current to control the shape of E-O frequency response.

As shown in FIG. 1B, the VCSELs of the prior art 130 are separately etched into individual mushroom shapes and each of the VCSELs emits light. However, it is in fact very difficult to make the VCSELs close to each other. Furthermore, the prior art 130 is set with only a single electrode while the present invention 120 uses two separate electrodes 12,13. During high-speed operation, an electrode 12 at a side of the present invention 120 is injected with direct current (DC) and the other electrode 13 at the other side is injected with DC along with radio frequency (RF) signals, where the electrodes 12,13 at two sides can be separately supplied with different currents; and, through the uneven distribution of currents, optical coupling is enhanced. Hence, the present invention 120 prepares DC light outputs of two neighboring VCSEL units 11 and inject the DC light outputs into modulated VCSEL pairs for obtaining a significant improvement in dynamic performance.

As shown in FIG. 1C, an epitaxial layer of the VCSEL unit 11 is grown on an n⁺-type gallium arsenide (GaAs) substrate according to the present invention. The substrate comprises 4 layers of multiple quantum wells (MQW) 14 of indium gallium arsenide/aluminum gallium arsenide (In_{0.07}Ga_{0.9}As/Al_{0.3}Ga_{0.7}As) (40/45 angstroms (Å)), which is sandwiched between 39 n-type pairs and 24 p-type pairs of distributed Bragg reflector of Al_{0.93}Ga_{0.07}As/Al_{0.15}Ga_{0.85}As 15,16; and an oxide layer of AlGaAs (not shown in the figure) is set above the MQW 14. Besides, the epitaxial layer further uses Zn diffusion, where, in FIG. 1C, the Zn diffusion aperture 17 (W_{Z}) is 7 μm wide, the light-emission aperture 18 (Wₒ) formed by oxidation and evacuation is 7 μm wide, and the Zn diffusion depth 19 (d) is 1.5 μm. Due to the detuning of red shift of gain peak by the self-heating of the present invention 120 under a high bias current and a high junction temperature, a significant improvement in 3-decibel E-O bandwidth of VCSEL is achieved.

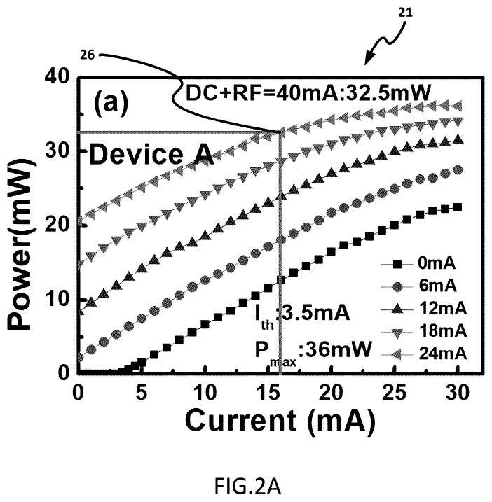

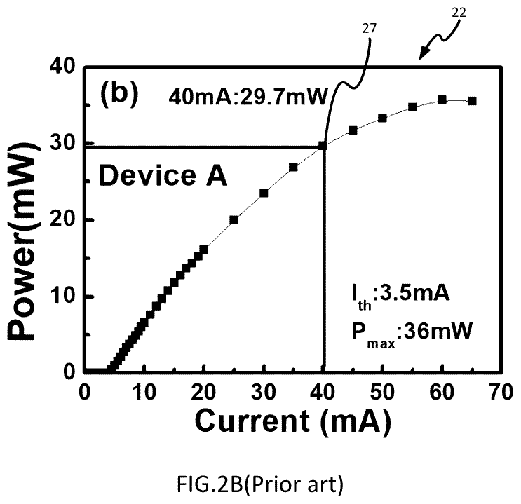

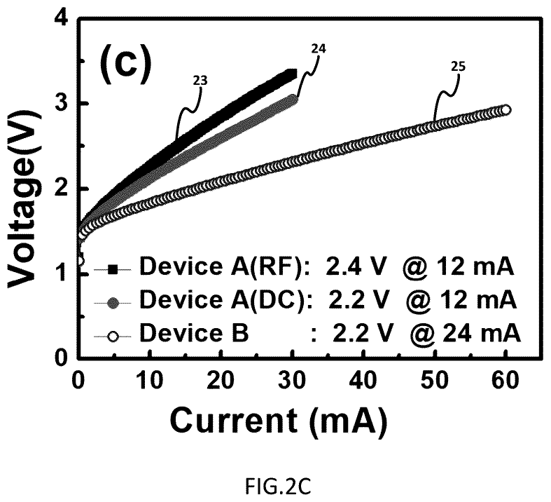

In FIG. 2A˜FIG. 2A, Diagram (a) and Diagram (b) show curves of light power to injected current (L-I curve) 21 of the present invention and the L-I curve 22 of the prior art; and Diagram (c) shows the current-to-voltage (I-V) curves 23,24 of the present invention and that 25 of the prior art with currents injected through a DC pad and an RF pad (W_{z}/Wₒ/d=7/7/1.5 μm). As shown in the figures, the present invention uses multiple electrodes with currents separately injected from the electrodes at two sides. As compared to the prior art with a single electrode directly injected with a single current of 40 milliamperes (mA), the present invention injects different currents to the electrodes at two sides to obtain a total current of the same. As compared to the prior art directly injected with the current of 40 mA into the single electrode, the present invention generates bigger optical power than the prior art. Therein, the current of DC+RF=40 mA injected from the present invention generates an optical power 26 of 32.5 milliwatts (mW) while the same current of 40 mA directly injected into the single electrode of the prior art only generates an optical power 27 of 29.7 mW. Hence, it is found that, with the same current injected, the optical power generate by the present invention is bigger than that of the prior art, which means that the speed feature of the present invention is obviously better.

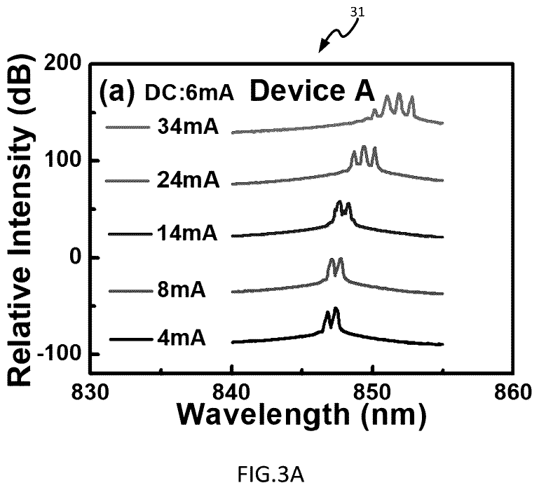

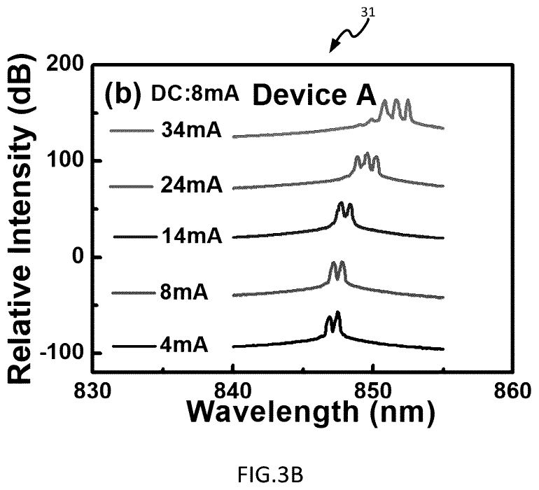

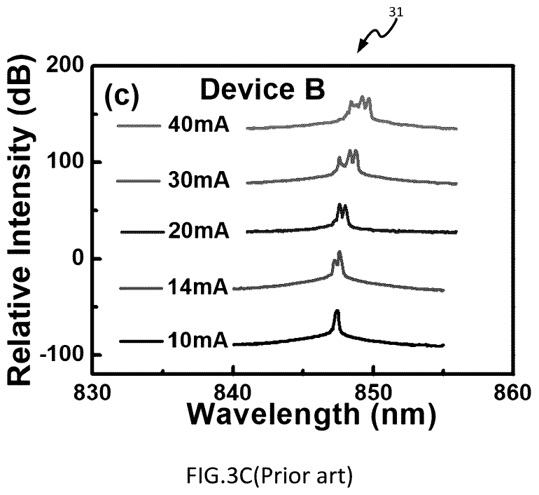

Moreover, it is also proved that, with currents separately injected through multiple electrodes, the present invention does not sacrifice frequency spectrum as compared to the prior art with a single electrode only. In FIG. 3A˜FIG. 3C, Diagram (a) and Diagram (b) show output spectra 31,32 of the present invention with the electrodes at two sides (DC electrode: 6 mA; DC electrode: 8 mA) under different bias currents; and Diagram (c) shows output spectra 33 of the prior art under different bias currents. As shown in the figures, the spectra 31,32 of the present invention are the same as that 33 of the prior art, which show a sustained spectrum performance.

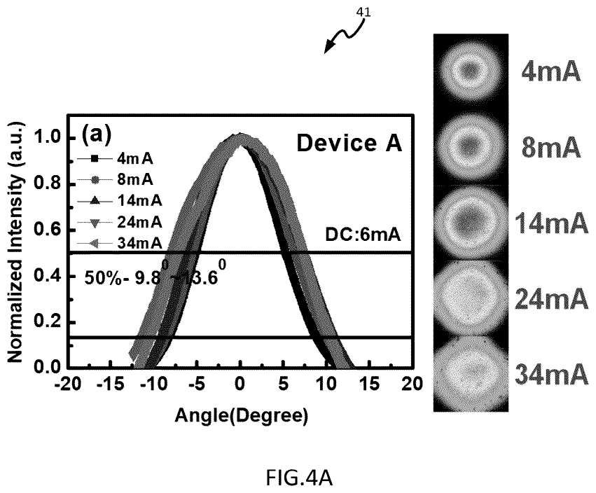

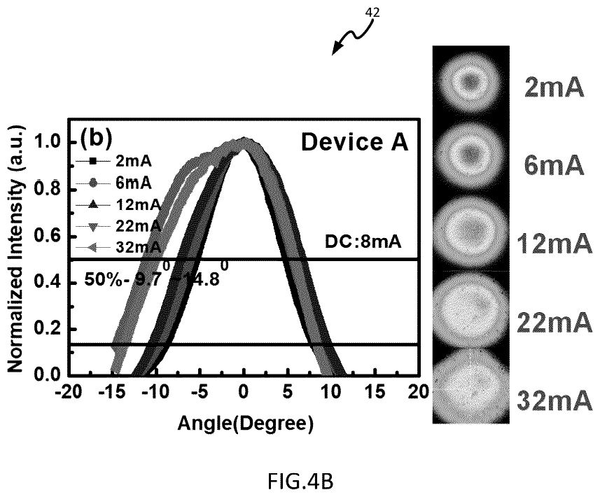

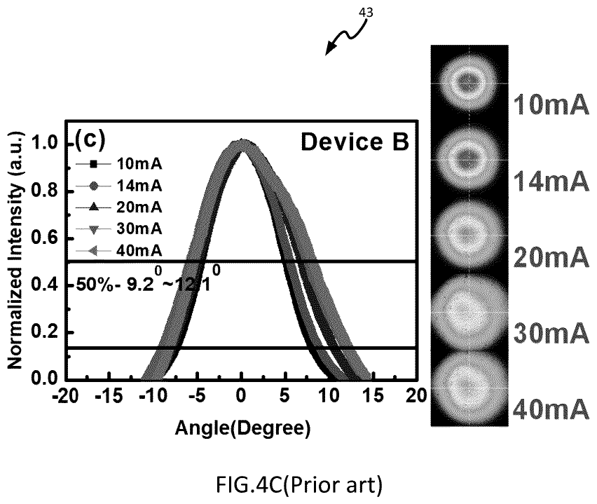

In FIG. 4A˜FIG. 4C, Diagram (a) and Diagram (b) show 1 D and 2D far-fields 41,42 of the present invention with the electrodes at two sides (DC electrode: 6 mA; DC electrode: 8 mA) under different bias currents; and Diagram (c) shows 1 D and 2D far-fields 43 of the prior art under different bias currents. As shown in the figures, in the far-field diagrams, the far fields 41,42 of the present invention is the same as those 43 of the prior art, remaining unchanged. It means that, by using the control method of the present invention with the same current injected, it is found that far fields and spectra remain unchanged.

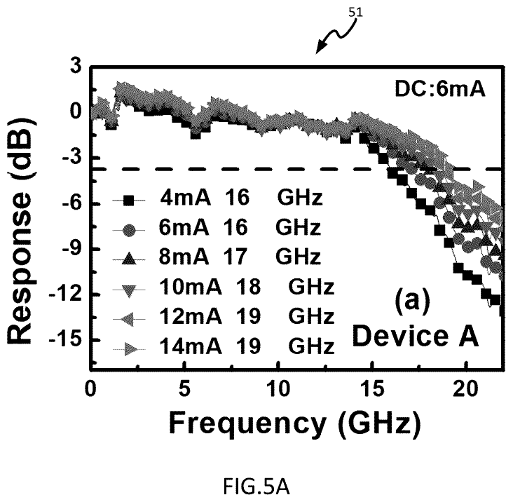

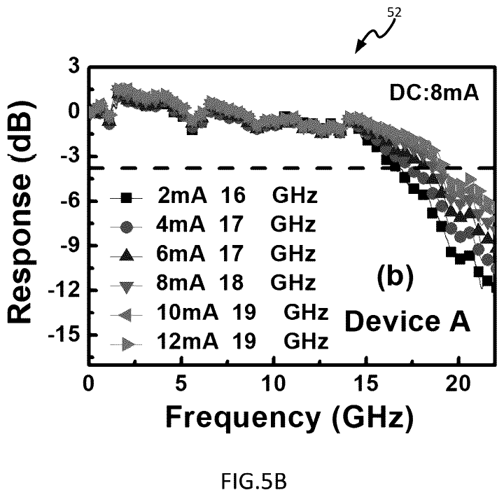

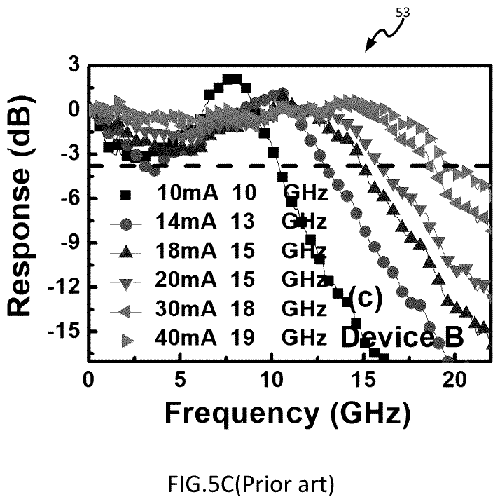

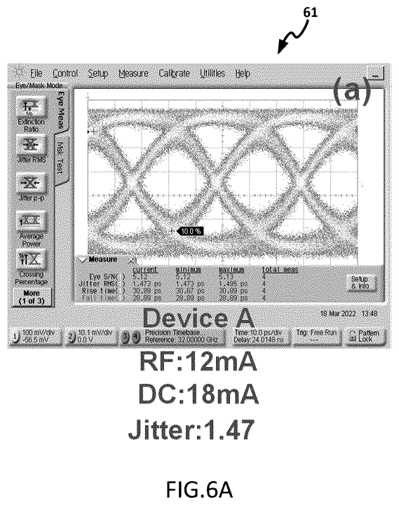

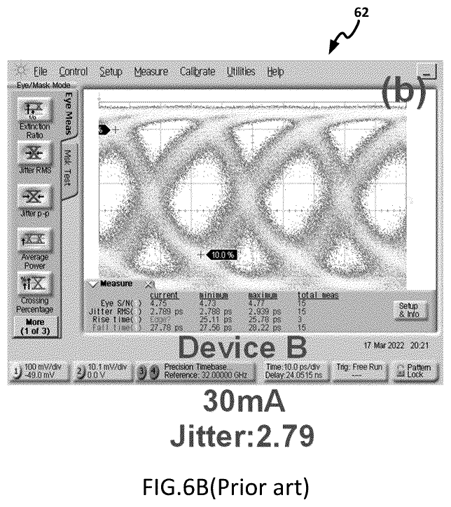

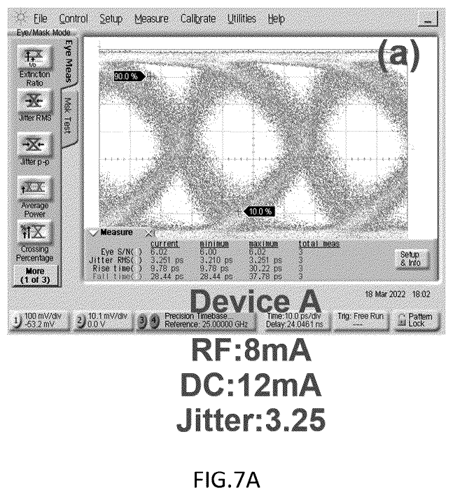

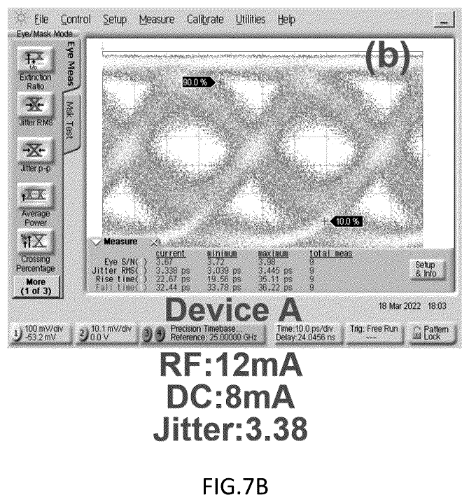

In FIG. 5A˜FIG. 5C, Diagram (a) and Diagram (b) show E-O frequency responses 51, 52 of the present invention with the electrodes at two sides (DC electrode: 6 mA; DC electrode: 8 mA) under different bias currents; and Diagram (c) shows E-O frequency responses 53 of the prior art under different bias currents. As shown in the figures, under the same current, the present invention exhibits flat curves of frequency response to velocity. In comparison, the prior art obtains frequency response with resonance and generates jumping phenomenon. In FIG. 6A and FIG. 6B, Diagram (a) and Diagram (b) show a BTB 32 Gbit/s transmission result 61 of the present invention and that 62 of the prior art. As shown in the figures, the eye patterns of the prior art are degraded and distorted with data transmission shorten; yet, the eye patterns of the present invention are clearly visible and square. In FIG. 7A and FIG. 7B, the data transmissions of the present invention is kept up to 500 meters.

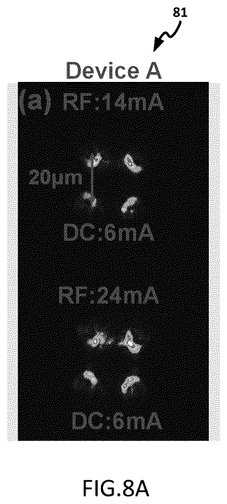

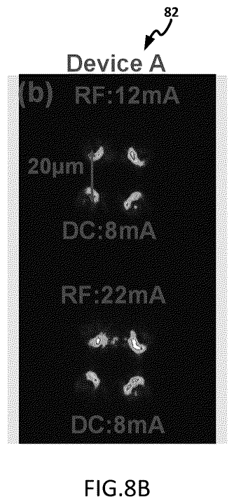

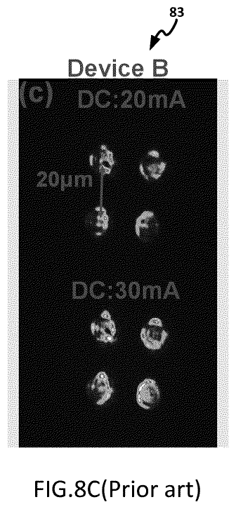

In FIG. 8A˜FIG. 8C, Diagram (a) and Diagram (b) show 2D near fields 81,82 of the present invention with the electrodes at two sides (DC electrode: 6 mA; DC electrode: 8 mA) under different bias currents; and Diagram (c) shows 2D near field 83 of the prior art under different bias currents. As shown in the figures, the present invention is set with the light-emission aperture on each of the VCSEL units in the VCSEL array; between every neighboring two of the light-emission apertures, a distance from a center of one of the light-emission apertures to a center of the other one of the light-emission apertures is less than 20 μm; and, with the use of multiple (two) electrodes injected with uneven currents for excitation as compared to the prior art of using a single electrode, the lights between the two light-emitting apertures of the present invention are coupled with each other. That is, the near-field diagrams prove that the present invention couples light; yet, the prior art does not.

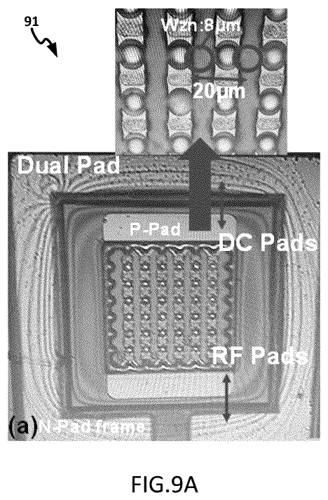

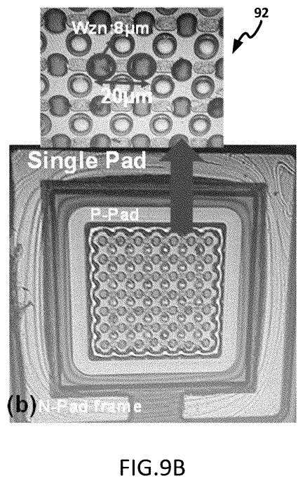

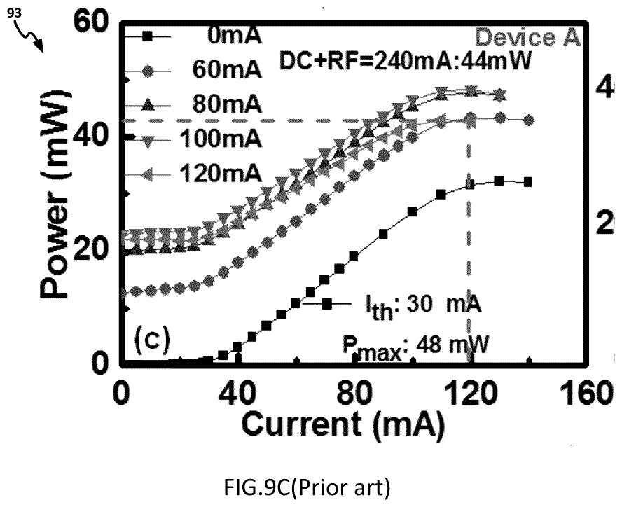

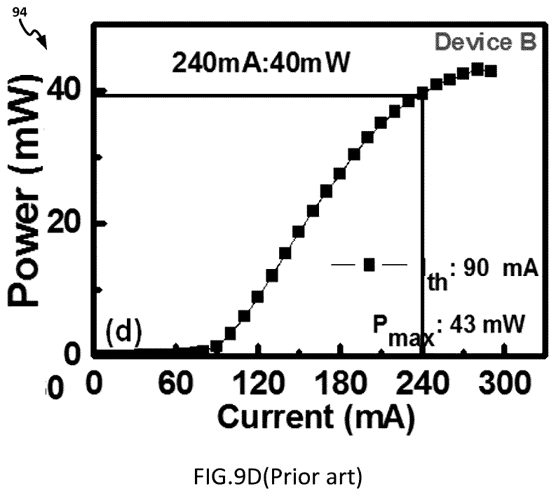

The above diagrams show the 2×2 VCSEL arrays and their performances. Another 7×7 VCSEL array is applied according to the present invention, where, between every neighboring two of the light-emission apertures, a distance from a center of one of the light-emission apertures to a center of the other one of the light-emission apertures is less than 20 μm; and the use of multiple (two) electrodes is applied. In FIG. 9A-FIG. 9A, Diagram (a) and Diagram (b) are a top-down diagram 91 of the present invention and that 92 of the prior art both using a 7×7 VCSEL array; and Diagram (c) and Diagram (d) are L-I curves 93 of the present invention with multi-electrode and an L-I curve 94 of the prior art with the single electrode. As shown in the figures, by using the 7×7-coupled VCSEL array of the prior art with the single electrode directly injected with a current of 240 mA, an optical power of 40 mW is obtained. Nevertheless, by using the 7×7-coupled VCSEL array of the present invention with the electrodes at two sides injected with a total current of DC+RF=240 mA, an optical power of 44 mW is obtained, which shows that the present invention increases the optical power.

In FIG. 10, 2D near fields, 1 D and 2D far fields 103,104, and E-O frequency responses are shown for the present invention with multi-electrode and the prior art with a single electrode, both using a 7×7-coupled VCSEL array under different bias currents. Therein, Diagram (c) shows the illustrations of transmission results of BTB 13 Gbit/s eye patterns. As shown in Diagram (a) and Diagram (b), with the uneven currents simultaneously injected into the multiple (two) electrodes, the present invention shows optical coupling 101, yet no coupling 102 occurs in the prior art with the single electrode. Moreover, the present invention has a beautiful performance of far field 103 as the standard 2×2 coupled VCSEL array 104, where no loss is found. Diagram (c) shows that the present invention uses multiple (two) electrodes for excitation to make frequency response flatter and eye pattern 105 better than the prior art whose frequency response jumps and eye pattern 106 is bad.

Thus, as is described above, the present invention uses multiple electrodes to synthesize E-O frequency response of VCSEL array, not limited to the two electrodes mentioned above. As having been proved by experiments, the present invention makes the optical power larger, the performance of far-field and spectrum as beautiful as the prior art using a single electrode, frequency response flatter, and eye pattern better; yet, the prior art has jumps in frequency response and bad eye pattern. From the near-field diagrams, it is found that the present invention has lights coupled to each other while there is no coupling found in the prior art.

To sum up, the present invention is a multi-electrode device using a VCSEL Array with improved E-O frequency response, where, with a light-emission aperture dug in each of dumbbell-shaped VCSEL units of a VCSEL array, a distance between every neighboring two of the light-emission apertures is less than 20 μm; and electrodes whose number are not smaller than two are assembled with each injected with a different current to make the VCSEL array synthesized for controlling the shape of E-O frequency response.

The preferred embodiment herein disclosed is not intended to unnecessarily limit the scope of the invention. Therefore, simple modifications or variations belonging to the equivalent of the scope of the claims and the instructions disclosed herein for a patent are all within the scope of the present invention.

What is claimed is:

1. A multi-electrode device using a vertical-cavity surface-emitting laser (VCSEL) array with improved electrical-to-optical (E-O) frequency response, comprising
a vertical-cavity surface-emitting laser (VCSEL) array of a plurality of arranged VCSEL units, wherein a light-emission aperture is deposed on each of said VCSEL units in said VCSEL array; between every neighboring two of said light-emission apertures, a distance from a center of one of said light-emission apertures to a center of the other one of said light-emission apertures is less than 20 microns (μm); electrodes whose number are not smaller than two are assembled; and each of said electrodes is injected with a different current to control the shape of electrical-to-optical (E-O) frequency response.

2. The multi-electrode device according to claim 1,
wherein said VCSEL array is arranged as an M×M array with said M as a positive integer not smaller than 2.

3. The multi-electrode device according to claim 1,
wherein each of said VCSEL units comprises distributed Bragg reflectors and multiple quantum wells.

4. The multi-electrode device according to claim 1,
wherein each of said VCSEL units further comprises zinc diffusion apertures.
